(19) United States
(12) Patent Application Publication
(10) Pub. No.: US 2007/0090726 A1
(43) Pub. Date: Apr. 26, 2007

(54) Piezoelectric fan

(76) Inventors: Grant Adam Morris, North Salem, IN (US); Jared Robert Brosch, Cicero, IN (US)

Correspondence Address: WOODARD, EMHARDT, MORIARTY, MCNETT & HENRY LLP, 111 MONUMENT CIRCLE, SUITE 3700, INDIANAPOLIS, IN, 46204-5137, US

(21) Appl. No.: 11/256,759

(22) Filed: Oct. 24, 2005

(51) Int. Cl. H01L 41/00

(52) U.S. Cl. 310/330

(57) ABSTRACT

A method of making a piezoelectric fan includes using a portion of the fan blade material as the substrate for the electronic circuit. By this method a single material may serve as both the substrate for the electronic circuitry and as the fanning end of the fan blade. Flex circuitry, including elements such as bleed resistors, inductors, capacitors, DC to AC conversion, shielding, or even drive circuitry, may be used. The piezoelectric material used to power the fan blade may have a Curie temperature high enough to survive reflow soldering, thus allowing the fan to be surface mountable on an electronic device. The fan may include an interconnect to facilitate connecting the piezoelectric material to the electronic circuit of the fan, and to facilitate connecting the electronic circuit of the fan to the electrical system of an electronic device. The interconnect may also facilitate mechanically mounting the fan.

### FIELD OF THE INVENTION

The present invention relates generally to piezo-electric fans, and more particularly to a piezoelectric fan having a simplified and improved construction.

### BACKGROUND TO THE INVENTION

Piezoelectric fans are typically composed of one or more pieces of piezoelectric ceramic laminated to a metal or polymer blade. The lamination can be done with a stack of ceramic on one side of the fan blade, or on both sides of the fan blade. The ceramic can be wired in a series or parallel configuration requiring one or more positive and negative leads.

A small electric circuit may be used to aid in the interconnection of the piezoceramic. Various electronic devices (surface mount or otherwise) such as bleed resistors, inductors, capacitors, DC to AC conversion, or even drive circuitry, may also be included. Ultimately, an AC excitation signal is usually applied to the ceramic. This causes the ceramic to flex in a back and forth bending motion. The fan blade, typically the same width as the ceramic but much longer, waves back and forth driven by the motion of the piezoelectric ceramic. This waving of the fan blade creates cooling wind currents that can be used to cool sensitive electronics among other uses.

With prior art construction methods the blade and the circuit have been two separate components, and have required two separate assembly steps to laminate them to the fan. Thus, prior art fans have been unnecessarily complex and costly to assemble.

A need therefore exists for a piezoelectric fan having a simplified and improved construction. The present invention addresses that need.

### SUMMARY OF THE INVENTION

Briefly describing one aspect of the present invention, there is provided a method of making a piezoelectric fan so that a portion of the fan blade material doubles as the substrate for the electronic circuit that powers and controls the fan. By this method a single component provides both the fanning portion and the electronic circuit portion of the fan. The single component may include flex circuitry at the electronic end, and may include devices such as bleed resistors, inductors, capacitors, DC to AC conversion, shielding, or even drive circuitry. A high-performance piezoelectric material that has a Curie temperature high enough to survive reflow soldering of the fan to an electronic device may be used to generate the fanning motion. The fan may include an interconnect to facilitate mounting the fan to an electronic device. The interconnect may also facilitate connecting the piezoelectric material to the electronic circuit of the fan, and the electronic circuit of the fan to the electrical system of the subject electronic device.

### DESCRIPTION OF THE DRAWINGS

FIG. 1 shows a piezoelectric fan as made by the methods of the prior art.

FIG. 2 shows one embodiment of the present invention.

FIGS. 3A-3C illustrate one method of manufacturing the piezoelectric fans of the present invention.

FIGS. 4A and 4B show an embodiment of the present invention including an interconnect to facilitate mounting and connecting the fan to an electronic device.

### DETAILED DESCRIPTION OF THE INVENTION

For the purposes of promoting an understanding of the principles of the invention, reference will now be made to certain embodiments and specific language will be used to describe the same. It will nevertheless be understood that no limitation of the scope of the invention is thereby intended, such alterations and further modifications of the illustrated embodiments being contemplated as would normally occur to one skilled in the art to which the invention relates.

As indicated above, one aspect of the present invention relates to the use of a single piece of material as both a fan blade and as the substrate for the electronic circuit of a piezoelectric fan. The distal end of the fan blade functions normally, while the proximal end of the fan blade extends beyond the piezoelectric ceramic and forms the substrate on which an electronic circuit layout, traces, or other connection points can be made. This dual use of the blade material reduces part count and complexity—providing a more efficient and simplified piezoelectric fan construction.

In another aspect of the invention a piezoelectric fan is provided with an interconnect to allow mounting and connecting the fan to a small electronic device. The interconnect may comprise one or more electrical contacts for connecting the fan circuitry to the electronic device, and may additionally comprise one or more mechanical contacts to anchor a portion of the piezoelectric material. The interconnect may also comprise connections for connecting all or portions of the piezoelectric material of the fan to the fan's electrical circuitry. The illustrated interconnect is particularly useful for surface mounting the fan, although mounting by a PCB thru-hole connection or some other method may also be accomplished with an appropriately configured interconnect.

As to the basic construction of the inventive fan, a single piece of material is used as both the substrate for the electrical circuit that drives the piezoelectric material, and as the fan blade. Thus, in some preferred embodiments only three materials are required to form the fan: the fan blade/substrate material, the piezoelectric material, and the electronic circuitry material. In some preferred embodiments, as described more fully below, a fourth material providing an interconnect to mount and anchor the fan may also be included.

Any material that can be appropriately formed and patterned to act as both a circuit and as a fan blade may be used to make the piezoelectric fan blade of the present invention. For example, in some preferred embodiments the fan blade may be made of a polyimide or a polyimide composite material. In other embodiments the fan blade may be made of polyester, polyethylene, silicon, polytetrafluoroethylene, biaxially-oriented polyethylene terephthalate polyester, liquid crystal polymer (LCP), etc. Thin rigid substrates like FR-4 PCG laminate may also be used. In some preferred embodiments the fan blade is made of a brand name material such as Kapton, Apical, Upilex, Pyralux, Teflon or Mylar.

A metalized layer may be deposited on the top, and/or bottom, and/or one or more sides of the fan blade to provide the electronic circuitry necessary to control the piezoelectric material that powers the fan. The metalized layer may be selectively applied through masks (an additive approach) or applied to the whole blade and then etched away appropriately (a subtractive approach).

A piezoelectric ceramic material may be bonded to either or both sides of the blade material, with at least a portion of the piezoelectric ceramic material being in contact with the electronic circuitry. In alternative embodiments the fan blade is formed so that short arms of the circuit-containing end of the material can be bent over on top of the ceramic to facilitate top as well as the bottom connections.

The circuit can be used as an attachment point for wires, a connector, or otherwise. Also the printed circuit can be used as stated above including devices such as bleed resistors, inductors, capacitors, DC to AC conversion, shielding, or even drive circuitry.

The fan may be adapted to vibrate at virtually any desired frequency/speed. In some embodiments of the invention multiple fans are used. When multiple fans are used, such fans may be adapted so that they vibrate at the same frequency/speed, or at different frequencies/speeds. The turbulence of the air flow generated by the fans may be affected by the vibration rates of the fans, with more turbulence potentially being provided by multiple fans vibrating at different frequencies/speeds. More or less air turbulence may therefore be provided by the fans according to the needs of a particular application.

In some embodiments an interconnect to facilitate connecting and mounting the fan is also provided. The interconnect may include one, two, or more electrical connections to connect the fan circuitry to the electrical circuitry of the device that will be cooled by the fan. Electrical connections to connect all or a portion of the piezoelectric material to the fan circuitry may also be included.

The interconnect may also include one or more mechanical connections, including mechanical connecting portions to facilitate mounting the fan to an electrical device and mechanical connecting portions to anchor a portion of the piezoelectric material so that it vibrates appropriately to provide effective fanning action. If a portion of the piezoelectric material is not anchored appropriately, the material will not create an effective fanning vibration.

In one preferred embodiment the interconnect comprises a “clamshell” design that opens to receive the electrical end of the fan, and snaps closed to make the appropriate internal electrical connections. For example, the clamshell may close to connect the piezoelectric material to the drive fan circuitry, and to connect the fan circuitry to external electrical connectors that can be soldered to the electronic device. In one embodiment of the clamshell connector there are three external connectors all of which provide mechanical connection points to mount the fan to an electronic device. One of the external connectors also provides a positive electrical connector, and one of the external connectors also provides a negative electrical connector. The remaining external connector is primarily a mechanical connection to provide tripod stability, and need not provide any electrical connection at all.

It is to be appreciated that the disclosed interconnect can be adapted to allow either flat or edge clamping of the fan so that the fan can be oriented in virtually any position relative to the device being cooled. This allows the fan to optimize airflow over or around the device.

In some embodiments a large piece of fan blade material is used to make a multiplicity of fans which are separated after the electronic circuitry and the piezoelectric material are provided. A piece of fan blade material having the width of several or many fans is provided with electronic circuitry at one end, and is overlayed with a piezoelectric material as illustrated below. The material is then cut into separate fans by making a series of longitudinal cuts at desired widths.

As to the sizes of the manufactured fans, the preferred embodiments are small enough to operate with very low power input, such as, for example, 3 to 5 volts of DC power. Such fans may be less than 3 mm wide and less than 15 mm long, with 1 mm by 12 mm fans (including the electrical circuitry end) being preferred for certain applications.

In some embodiments the piezo fan may be engineered to operate with a power input of 3 to 12 volts of DC voltage. In such embodiments the electronic circuitry of the fan is designed to be capable of handling that power range as an input, and may have internal regulation to provide the chip with the power it actually needs. Other embodiments are designed to operate with a power input of 1 to 5 volts DC power, or less.

In alternate embodiments the fan may be adapted to operate using AC power without requiring DC to AC conversion in the electronic circuitry of the fan. For example, an electronic device may have an AC power source, or the device may have a DC power source and a DC to AC power converter that is external to the fan.

In some embodiments the piezoelectric material is a material having a Curie temperature high enough to survive reflow soldering of the formed fan to the surface of an electronic device. In the most preferred embodiments the Curie temperature is at least 50° C. higher than any short or long term temperature to which the fan material may be exposed. Preferably the piezoelectronic material can survive exposure to temperatures of at least 210° C., and more preferably at least 240° C., for at least one minute. Most preferably the piezoelectronic material can survive exposure to temperatures of at least 260° C. for at least ninety seconds. In some embodiments the piezoelectronic material is engineered to survive at least short-term exposure to temperatures of at least 300° C., while in other embodiments the piezoelectronic material is designed to survive exposure to temperatures of at least 350° C. Acceptable piezoelectric materials are described, for example, in commonly owned U.S. patent application Ser. No. 10/686,310 of Liufu, which is incorporated herein by reference.

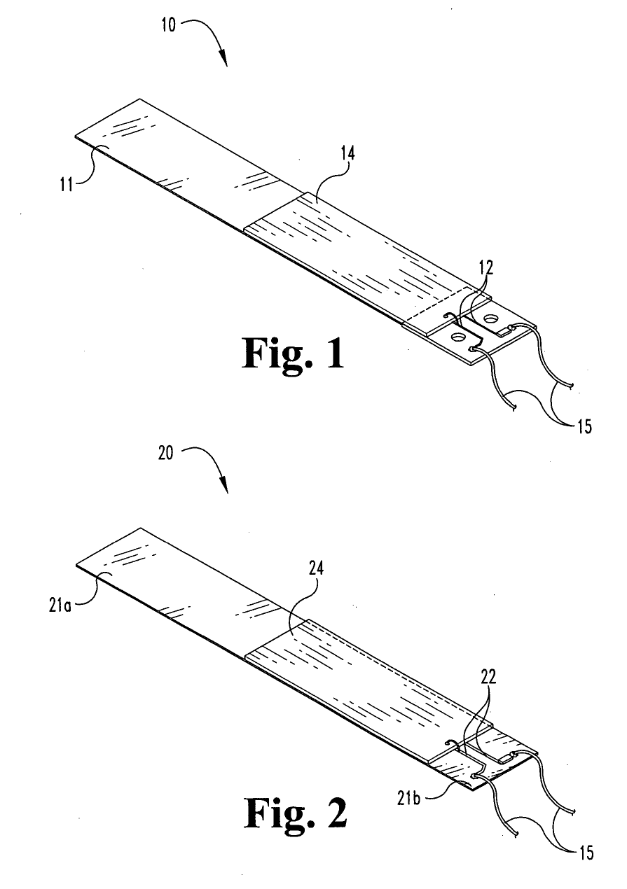

Referring now to the drawings, FIG. 1 shows a prior art piezoelectric fan 10 comprising a fan blade 11, electronic circuitry 12 on a substrate 13, and a piezoelectric material 14. Lead wires 15 connect electronic circuitry 12 to a power source (not shown).

FIG. 2 shows a piezoelectric fan according to one embodiment of the present invention. Fan 20 includes a material 21 that acts as both a fan blade and as a substrate for electronic circuitry 22. Accordingly, material 21 comprises a distal fanning end portion 21a and a proximal electrical end portion 21b. (For the purposes of this disclosure, distal and proximal are used as they naturally relate to the fan blade as used, with the distal end being the end that is free to vibrate in a fanning motion, and the proximal end being the end that is typically fixed to a device being fanned.) A piezoelectric material 24 is provided so that it overlays and contacts both the distal fanning end portion 21a and the proximal electrical end portion 21b. The piezoelectric material is selected and configured so as to be effective for causing the fan blade material to vibrate in a fanning motion when powered and/or controlled by the electronic circuitry.

It is to be appreciated that the relative proportions of the distal fanning end portion and the proximal electrical end portion may be varied according to the specific needs of a fan, with the proportions shown in the drawings being illustrative only. In some embodiments the distal fanning end may be significantly longer, while in other embodiments the distal fanning portion may be substantially shorter.

The use of flex circuitry allows the proximal end of the fan to be bent or twisted so that it may be more easily connected or attached to a device being fanned.

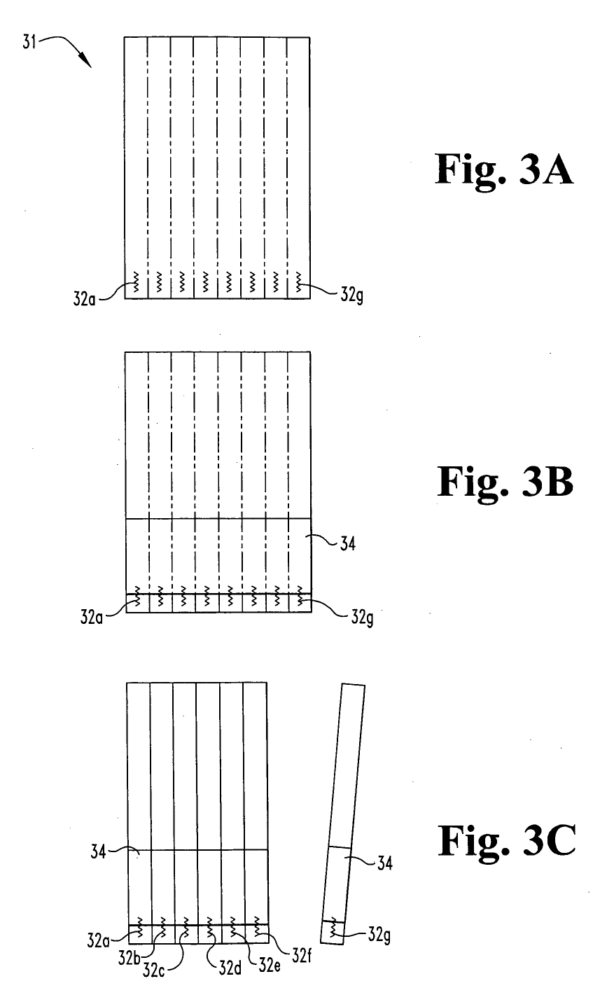

In some embodiments multiple fans are manufactured from a single piece of blade material. As shown in FIG. 3A, a sheet of material 31 may be provided with multiple electronic circuits 32a-g spaced apart to allow separation of individual fan elements by cutting between the circuits. A piece of piezoelectric material 34 is then provided on sheet 31 so that it contacts each electronic circuit 32a-g, as shown in FIG. 3B. Sheet 31 may then be cut as shown to provide multiple fans from the single sheet of material, as shown in FIG. 3C.

As indicated previously, the size of each fan may be selected according to the needs of a particular customer. Individual fans may commonly be, for example, 1 to 5 mm wide and 10 to 30 mm long, although smaller or larger fans are contemplated as being within the scope of the present invention. In one preferred embodiment the fans are about 1 mm wide and between 10 mm and 15 mm (preferably about 12 mm) long, including both the vibrating and the non-vibrating portions of the fan.

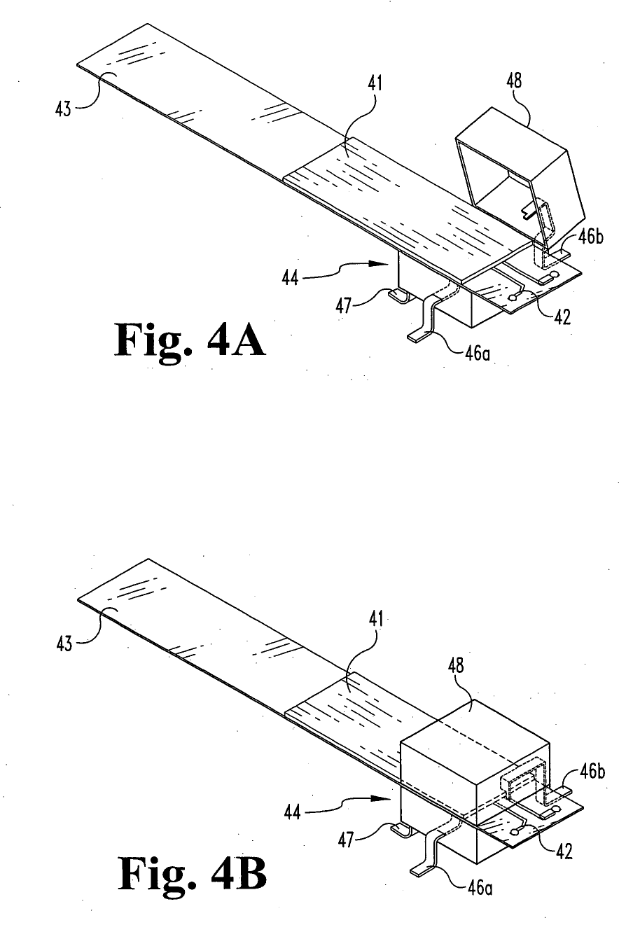

FIGS. 4A and 4B show a piezoelectric fan that includes a snap-on interconnect 44 to facilitate mounting and connecting the fan to an electronic device. Piezoelectric material 41 and electric circuitry 42 are provided on fan blade 43 as described above, with interconnect 44 at least partially surrounding and holding those components. The illustrated interconnect 44 includes a pair of electrical contacts 46a and 46b for connecting the electrical circuitry to the electronic device, and one or more mechanical contacts 47 for holding the fan on the electrical device. The main body 48 of interconnect 44 clamps the piezo portion of the fan and houses the electrical connections.

As shown in FIG. 4A, interconnect 44 may be formed in a clamshell design that allows the fan blade (with its piezoelectric material and electronic circuitry) to be quickly and easily installed in an electronic device. After the fan blade is placed in the interconnect, the clamshell is closed (as shown in FIG. 4B) to establish electrical connections between the electronic circuitry, the piezoelectric material, and the external connectors. In the illustrated device external connector 46a provides one electrical connection to the fan circuitry, and external connector 46b provides another electrical connection to the fan circuitry and additionally connects the fan circuitry to the top surface of the piezoelectric material. The external connectors may then be connected to the electronic device, such as by soldering the connectors to the device.

The interconnect of FIGS. 4A-4B is particularly useful when combined with the manufacturing method of FIGS. 3A-3C. By that combination a sheet of material appropriate to make a multiplicity of piezoelectric fans is provided, and a multiplicity of traces is put down on the sheet so that individual fans can eventually be formed. One or more “bands” of piezoelectric material is then applied to the sheet, with the piezoelectric material being positioned so that individual fans will be formed when the material is cut. The individual fans are separated, and each fan is provided with an interconnect to facilitate connecting the fan circuitry to the circuitry of an electronic device to be fanned. The interconnect is mounted to the electronic device, thereby stabilizing the fan and making the appropriate electrical connections.

While the invention has been illustrated and described in detail in the drawings and foregoing description, the same is to be considered as illustrative and not restrictive in character, it being understood that all changes and modifications that come within the spirit of the invention are desired to be protected.

1. A method of making a piezoelectric fan, comprising:
a) providing a fan blade material sized and shaped for use as a piezoelectric fan blade, said fan blade material having a distal fanning end portion and a proximal electrical end portion;
b) providing electrical circuitry on the proximal electrical end portion of said fan blade material, wherein said electrical circuitry is effective for powering and/or controlling a piezoelectric material; and
c) fixing a piezoelectric material to at least a part of said distal fanning end portion and to at least a part of said proximal electrical end portion, wherein said piezoelectric material is effective for causing the distal fanning end portion of said fan blade material to vibrate in a fanning motion;
wherein a single layer of material is used as the substrate for said electrical circuitry and as the fanning portion of said fan blade material.

2. The method of claim 1 wherein said “providing electrical circuitry” step comprises printing or patterning an electrical circuit on the proximal electrical end portion of said fan blade material.

3. The method of claim 1 wherein said “providing electrical circuitry” step comprises providing a flexible printed circuit on the proximal electrical end portion of said fan blade material.

4. The method of claim 1 wherein said method includes depositing a metalized layer on at least one surface of said fan blade material.

5. The method of claim 4 wherein said metalized layer is selectively applied to provide an electronic circuit.

6. The method of claim 4 wherein a portion of said metalized layer is selectively etched away to provide an electronic circuit.

7. The method of claim 1 wherein said “fixing a piezoelectric material” step comprises fixing a stack of at least two piezoelectric elements to said fan blade material.

8. The method of claim 1 wherein said piezoelectric material comprises a piezoelectric ceramic.

9. The method of claim 1 wherein said fan blade material comprises a polyimide.

10. The method of claim 1 wherein said fan blade material comprises a polyimide composite.

11. The method of claim 1 wherein said fan blade material comprises a polyester.

12. The method of claim 1 wherein said fan blade material comprises a liquid crystal polymer.

13. The method of claim 1 wherein said fan blade material comprises silicon.

14. The method of claim 1 wherein said electronic circuitry includes one or more resistors.

15. The method of claim 1 wherein said electronic circuitry includes one or more inductors.

16. The method of claim 1 wherein said electronic circuitry includes one or more capacitors.

17. The method of claim 1 wherein said electronic circuitry includes DC to AC conversion circuitry.

18. The method of claim 1 wherein said electronic circuitry includes drive circuitry.

19. The method of claim 1 wherein said method includes folding at least a part of the proximal electrical end portion of said fan blade material over at least part of said piezoelectric material to facilitate top as well as bottom connections to the piezoelectric material.

20. The method of claim 1 wherein a single material is used to form said distal fanning end portion and said proximal electrical portion of said fan blade.

21. The method of claim 1 wherein said piezoelectric material is a material having a Curie temperature of at least 210° C.

22. The method of claim 1 wherein said piezoelectric material is a material having a Curie temperature of at least 240° C.

23. The method of claim 1 wherein said piezoelectric material is a material having a Curie temperature of at least 260° C.

24. A piezoelectric fan, comprising:
a) a fan blade material sized and shaped for use as a piezoelectric fan blade, said fan blade material having a distal fanning end portion and a proximal electrical end portion;
b) electrical circuitry on the proximal electrical end portion of said fan blade material, wherein said electrical circuitry is effective for powering and/or controlling a piezoelectric material; and
c) a piezoelectric material fixed to at least a part of said proximal electrical end portion and to at least a part of said distal fanning end portion in a manner effective to power the distal fanning end portion of said fan blade material in a fanning motion;
wherein a single layer of material is used as the substrate for said electrical circuitry and as the fanning portion of said fan blade material.

25. The fan of claim 24 wherein said one or more electrical connections comprises a printed or patterned electrical circuit on the proximal electrical end portion of said fan blade material.

26. The fan of claim 24 wherein said one or more electrical connections comprises a flexible printed circuit on the proximal electrical end portion of said fan blade material.

27. The fan of claim 24 wherein said fan includes a metalized layer on at least one surface of said fan blade material.

28. The fan of claim 27 wherein said metalized layer has been selectively applied to provide an electronic circuit.

29. The fan of claim 27 wherein a portion of said metalized layer has been selectively etched away to provide an electronic circuit.

30. The fan of claim 24 wherein said piezoelectric material comprises a stack of at least two piezoelectric elements.

31. The fan of claim 24 wherein said piezoelectric material comprises a piezoelectric ceramic.

32. The fan of claim 24 wherein said fan blade material comprises a polyimide.

33. The fan of claim 24 wherein said fan blade material comprises a polyimide composite.

34. The fan of claim 24 wherein said fan blade material comprises a polyester.

35. The fan of claim 24 wherein said fan blade material comprises a liquid crystal polymer.

36. The fan of claim 24 wherein said fan blade material comprises silicon.

37. The fan of claim 24 wherein said electronic circuitry includes one or more resistors.

38. The fan of claim 24 wherein said electronic circuitry includes one or more inductors.

39. The fan of claim 24 wherein said electronic circuitry includes one or more capacitors.

40. The fan of claim 24 wherein said electronic circuitry includes DC to AC conversion circuitry.

41. The fan of claim 24 wherein said electronic circuitry includes drive circuitry.

42. The fan of claim 24 wherein said at least a part of the proximal electrical end portion of said fan blade material is folded over at least part of said piezoelectric material to facilitate top as well as bottom connections to the piezoelectric material.

43. The fan of claim 24 wherein said piezoelectric material is a material having a Curie temperature of at least 210° C.

44. The fan of claim 24 wherein said piezoelectric material is a material having a Curie temperature of at least 240° C.

45. The fan of claim 24 wherein said piezoelectric material is a material having a Curie temperature of at least 260° C.

46. The fan of claim 24 and further including an interconnect to facilitate mounting and connecting the fan to an electronic device.

47. The fan of claim 46 wherein said interconnect includes a pair of external electrical connectors for electrically connecting the fan to an electrical device.

48. The fan of claim 46 wherein said interconnect includes at least one external mechanical connector for mechanically counting the fan to an electrical device.

49. The fan of claim 24 wherein said fan blade is no more than about 1 mm wide and operates using a DC power source of no more than 12 volts.

50. The fan of claim 24 wherein said fan can operate using a DC power source of no more than 5 volts.
